(19) United States
(12) Patent Application Publication
(10) Pub. No.: US 2010/0213576 A1
(43) Pub. Date: Aug. 26, 2010

(54) METHOD FOR PRODUCING GROUP III NITRIDE CRYSTAL SUBSTRATE, GROUP III NITRIDE CRYSTAL SUBSTRATE, AND SEMICONDUCTOR DEVICE USING GROUP III NITRIDE CRYSTAL SUBSTRATE

(75) Inventors: Kouichi Hiranaka, Ehime (JP); Hisashi Minemoto, Osaka (JP); Takeshi Hatakeyama, Ehime (JP); Osamu Yamada, Ehime (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/681,718

(22) PCT Filed: Oct. 8, 2008
(86) PCT No.: PCT/JP2008/002834

§ 371 Date: Apr. 5, 2010

(30) Foreign Application Priority Data
Oct. 9, 2007 (JP) 2007-262815

(51) Int. Cl. H01L 29/20; H01L 21/20; H01L 21/66

(52) U.S. Cl. 257/615; 438/478; 438/16; 257/E29.089; 257/E21.09; 257/E21.53

(57) ABSTRACT

Disclosed is a method for producing a group III nitride crystal substrate. A group III nitride crystal is formed by a growth method using a flux. The group III nitride crystal substrate is heat treated at a temperature equal to or higher than the lowest temperature at which the flux contained inside the group III nitride crystal substrate through intrusion into the crystal during the crystal formation can be discharged to outside the group III nitride crystal substrate, and equal to or lower than the highest temperature at which the surface of the group III nitride crystal substrate is not decomposed.

### TECHNICAL FIELD

The present invention relates to a method for producing a group III nitride crystal substrate by using a flux growth method, the group III nitride crystal substrate and a semiconductor device using the group III nitride crystal substrate.

### BACKGROUND ART

Group III nitride crystal semiconductors such as a gallium nitride (GaN) crystal semiconductor are attracting attention as the materials for blue light or ultraviolet light-emitting semiconductor elements. Blue light-emitting laser diodes (LDs) are applied to high-density optical discs or high-density displays, and blue light-emitting diodes (LEDs) are applied to displays or illumination. Ultraviolet LDs are expected to be applied to biotechnology and the like, and ultraviolet LEDs are expected to be applied as ultraviolet light sources for fluorescent lamps. Further, recently applications of the group III nitride crystal semiconductors to high-frequency high-power devices have also been investigated.

A gallium nitride substrate, which is one of the group III nitride crystal substrates for use in LDs and LEDs, is usually formed by vapor phase epitaxial growth (for example, the HVPE method: the hydride vapor phase epitaxy method). The apparatus used for the HVPE method has a quartz reaction tube and an electric furnace equipped with a resistance heater for heating the quarts reaction tube. To the quartz reaction tube, a first gas introduction port, a second gas introduction port and an exhaust gas port are connected. From the first gas introduction port, a mixed gas composed of hydrogen chloride gas and hydrogen gas is introduced. From the second gas introduction port, a mixed gas composed of ammonia gas and hydrogen gas is introduced. In a reaction chamber, a source port of a Ga starting material is disposed. Hydrogen chloride is introduced from the first gas introduction port into the source port of the Ga starting material and gallium chloride is generated. The gallium chloride and the ammonia introduced from the second gas introduction port are reacted with each other, and thus a gallium nitride crystal is grown. The gallium nitride is grown on a substrate disposed in the quartz reaction tube and heated with the resistance heater.

As the substrate, usually a sapphire substrate is used. The dislocation density of the crystal obtained by this method is usually 10⁸ cm⁻² to 10⁹ cm⁻², and hence the reduction of the dislocation density is an important problem (for example, JP2000-12900A).

Alternatively, instead of vapor phase epitaxial growth, methods for growing crystals in liquid phase have also been investigated. However, the nitrogen equilibrium vapor pressure at the melting point of the crystal of a group III nitride such as GaN is 10000 atm (10000×1.013×10⁵ Pa) or more. Accordingly, it has been generally accepted that, for the purpose of growing GaN in the liquid phase, the conditions set at 1600° C. and 10000 atm (a high-temperature high-pressure growth method) are required (for example, Journal of Crystal Growth, Vol. 178, (1997), pp. 174 to 188). In a growth method that is performed under such high-temperature high-pressure conditions, the space that can be pressurized is extremely narrow, and it is difficult to form in such a narrow space a crystal having a large area of 2 inches or more required for production of a device as a final product. Additionally, a large high-temperature high-pressure synthesis apparatus for producing a large area substrate impractically leads to an increase in cost.

Recently, in a nitrogen gas atmosphere, a mixture composed of Ga as a starting material and sodium (Na) as a flux is melted at 800° C. and 50 atm (50×1.013×10⁵ Pa), and single crystals having a maximum crystal size of about 1.2 mm have been obtained by using the resulting melt, with a growth time of 96 hours (for example, JP2002-293696A). The gallium nitride crystals formed by this “sodium flux liquid phase growth method” usually have a dislocation density of 10⁵ cm⁻² to 10⁶ cm⁻². In other words, high-quality gallium nitride crystals lower in dislocation density as compared to the gallium nitride crystals produced by the vapor phase epitaxial growth are formed (for example, Japanese Journal of Applied Physics, Vol. 45, (2006) pp. L1136 to L1138).

The gallium nitride crystals formed by “the sodium flux liquid phase growth method” frequently include metals such as Na, K, Li and Ca that are the main components of the flux enabling a low-temperature low-pressure synthesis. The metals need to be removed. This is because the diffusion of these metal elements over the epitaxial film grown on the gallium nitride crystal substrate disturbs the control of the conduction type of the epitaxial film, and consequently the reliability of a semiconductor device such as a laser diode or a light-emitting diode may be degraded.

Known techniques adopt a production method in which: on the basis of the knowledge that the flux tends to deposit in the interface between the seed crystal substrate and the crystal undergoing liquid phase growth in the initial stage of the liquid phase growth or the flux tends to deposit in the vicinity of the surface of the crystal after the completion of the growth, by performing a step of removing the flux after the completion of the liquid phase growth and then by performing a heat treatment at a temperature of 300° C. to 800° C., the flux component in the vicinity of the both interfaces of the gallium nitride crystal is made to deposit on the surface of the gallium nitride crystal to be removed (for example, JP2004-224600A).

Further, there has been known a technique to prevent the diffusion of the impurities contained in the crystal in the liquid phase growth method of a group III nitride crystal using a flux. This is a technique in which the impurities on the surface of the group III nitride crystal are heat treated to be converted into inorganic compounds, and thus the diffusion of the impurities from the substrate is prevented (for example, JP2006-36622A).

On the other hand, there has been proposed a method for forming a single crystal of gallium nitride (GaN), which is a group III nitride crystal semiconductor, by applying an ammonothermal method (for example, Journal of Crystal Growth, Vol. 287, (2006), pp. 376 to 380). The ammonothermal method is a method in which gallium or gallium nitride is dissolved in ammonia, a supercritical fluid, and single crystals of gallium nitride are deposited by varying the temperature. The supercritical fluid means a fluid in the state exceeding the state in which the temperature limit and the pressure limit (critical point) at which ammonia in the gas state and ammonia in the liquid state can coexist. Such a supercritical fluid exhibits the properties different from the properties of the usual gas and liquid, and acts as a flux for use in the growth of the group III nitride crystal.

### DISCLOSURE OF THE INVENTION

### Problems to be Solved by the Invention

The present inventors precisely measured, by the secondary ion mass spectrometry, the thermal diffusion of the sodium as the main component of the flux inside the gallium nitride crystal produced by the known sodium flux liquid phase growth method, and consequently discovered that sodium remained not only in the vicinity of the surface of the gallium nitride crystal but also inside the gallium nitride crystal.

As described above, in the known technique, only the flux in the vicinity of the surface of the produced gallium nitride crystal is removed. In other words, the known technique cannot remove the flux remaining inside the crystal, and accordingly, when the gallium nitride crystal is sliced and thus a gallium nitride crystal substrate is formed, there is a possibility that sodium remains in the vicinity of the surface of the gallium nitride crystal substrate. When the gallium nitride crystal with sodium remaining therein is sliced to complete the production of a gallium nitride crystal substrate for use in formation of a semiconductor device, and the substrate is heated to a temperature of 1050° C. to 1100° C. and subjected to an epitaxial film growth by a known method to form a semiconductor element, then the remaining sodium is thermally vaporized, and thus disadvantageously the surface of the gallium nitride crystal substrate and the epitaxially grown film are damaged.

In the case of the gallium nitride crystal substrate formed by the ammonothermal method, when the substrate is similarly heated for growing an epitaxial film, the liquid-state ammonia contained in the macro-defects in the crystal is vaporized to blow out and thus disadvantageously the substrate is broken. In particular, the crystal growth temperature is usually 600° C. or lower in the ammonothermal method, but the operating temperature in the semiconductor device production is as high as 1000 to 1200° C., leading to a large temperature difference between these two temperatures. Accordingly, when there are even a few macro-defects that contain ammonia as condensed therein, the crystal may be broken at a temperature for growing a thin film to produce a semiconductor device.

Further, when an alkali-based substance is contained as a mineralizer in ammonia, there is a possibility that an alkali metal or an alkali earth element is similarly deposited outside the substrate in the production of a semiconductor device to degrade the device performances.

An object of the present invention is to remove the flux, exerting adverse effects at the time of the epitaxial growth, from a group III nitride crystal substrate produced by the flux growth method, for the purpose of solving the above-described problems.

### Means for Solving the Problems

For the purpose of achieving the above-described object, the present invention includes: a crystal forming step of forming a group III nitride crystal by a growth method using a flux; a slicing step of slicing the group III nitride crystal to form a group III nitride crystal substrate; and a heat treating step of heat treating the group III nitride crystal substrate at a temperature equal to or higher than the lowest temperature at which the flux contained inside the group III nitride crystal substrate through intrusion into the crystal in the crystal forming step can be discharged to outside the group III nitride crystal substrate, and equal to or lower than the highest temperature at which the surface of the group III nitride crystal substrate is not decomposed.

According to the present invention, preferably further included is a removing step of removing, by cleaning the group III nitride crystal substrate, the flux discharged by the heat treating step to outside the group III nitride crystal substrate and attached to the substrate.

According to the present invention, preferably further included is a planarizing step of planarizing the surface of the group III nitride crystal substrate after the heat treating step. The planarizing step is a treating step including at least one of or a combination of two or more of polishing, dry etching and wet etching to preferably planarize the surface of the group III nitride crystal substrate in such a way that the surface arithmetical mean roughness of the group III nitride crystal substrate is 0.1 nm to 5 nm.

According to the present invention, in the slicing step, the group III nitride crystal is preferably sliced in such a way that the thickness of the group III nitride crystal substrate is 200 μm to 800 μm.

According to the present invention, in the crystal forming step, preferably used is a flux including at least one of an alkali metal and an alkali earth metal, or a flux including ammonia in the supercritical state.

According to the present invention, a flux including sodium is preferably used. In this case, in the heat treating step, a heat treatment is preferably performed at 883° C. or higher and 1200° C. or lower.

According to the present invention, preferably, in the crystal forming step, a flux including ammonia in the supercritical state and a mineralizer is used, and in the heat treating step, the ammonia and the mineralizer contained inside the group III nitride crystal substrate are discharged to outside the group III nitride crystal substrate in the heat treating step.

According to the present invention, the group III nitride is preferably a compound including nitrogen and gallium.

According to the present invention, after the heat treating step, preferably included is an examining step of optically examining the macro-defect amount. In this case, an area ratio between the defective portions and the normal portions of the group III nitride crystal substrate as examined from the principal surface side of the group III nitride crystal substrate is preferably defined as the macro-defect amount.

The group III nitride crystal substrate of the present invention is a group III nitride crystal substrate produced by the above-described production method or methods, wherein the flux atomic concentration on the surface of the substrate and in the vicinity of the surface of the substrate is lower than the flux atomic concentration in the substrate portion more inner than the surface of the substrate and the vicinity of the surface of the substrate.

According to the group III nitride crystal substrate of the present invention, the macro-defect amount is preferably capable of being optically examined. In this case, the macro-defect amount is preferably an area ratio between the defective portions and the normal portions of the group III nitride crystal substrate as examined from the principal surface side of the group III nitride crystal substrate. The macro-defect amount is preferably 1% or less.

The semiconductor device of the present invention is a semiconductor device produced by forming, on a group III nitride crystal substrate produced by the above-described production method or methods, a group III nitride crystal semiconductor layer and a group III nitride crystal semiconductor element disposed on the group III nitride crystal semiconductor layer.

In the semiconductor device of the present invention, the group III nitride crystal semiconductor element is preferably a laser diode or a light-emitting diode.

According to the above means, it is possible to remove the flux, exerting adverse effects at the time of the growth of the epitaxial film, from the group III nitride crystal substrate produced by the flux growth method.

### ADVANTAGE OF THE INVENTION

According to the present invention, when a group III nitride crystal substrate is produced by the flux growth method, the flux can be effectively discharged from the substrate by vaporizing to discharge from the substrate the flux present inside the group III nitride crystal substrate by a high-temperature heat treatment, after the slicing step and before the growth of the epitaxial film.

### BRIEF DESCRIPTION OF THE DRAWINGS

FIG. 1 is a flow chart showing a method for producing a group III nitride crystal substrate of Embodiment 1 of the present invention;

FIG. 2A is a sectional view illustrating the step of producing the group III nitride crystal substrate of Embodiment 1 of the present invention;

FIG. 2B is a sectional view illustrating the step next to FIG. 2A;

FIG. 2C is a sectional view illustrating the step next to FIG. 2B;

FIG. 2D is a sectional view illustrating the step next to FIG. 2C;

FIG. 2E is a sectional view illustrating the step next to FIG. 2D;

FIG. 3 is a flow chart showing a method for producing a group III nitride crystal substrate of Embodiment 2 of the present invention;

FIG. 4 is a graph showing the results of the secondary ion mass spectrometry measurement for the case of the heat treatment temperature of 900° C. in Example 1 of the present invention;

FIG. 5 is a graph showing the results of the secondary ion mass spectrometry measurement for the case of the heat treatment temperature of 800° C. in Comparative Example 1; and

FIG. 6 is a sectional view illustrating the structure of a semiconductor laser diode of Example 3 of the present invention.

### BEST MODE FOR CARRYING OUT THE INVENTION

The embodiments of the present invention are described with reference to the accompanying drawings. Here, it is to be noted that in the drawings, the same symbols are given to the same or the corresponding members and the like.

### Embodiment 1

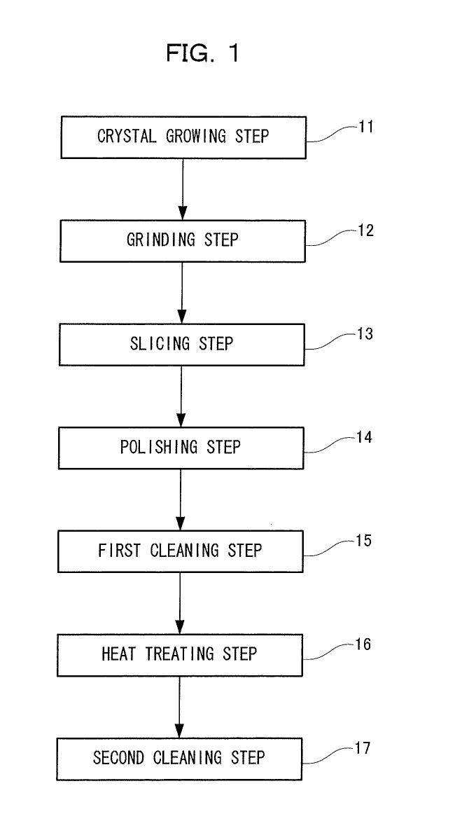

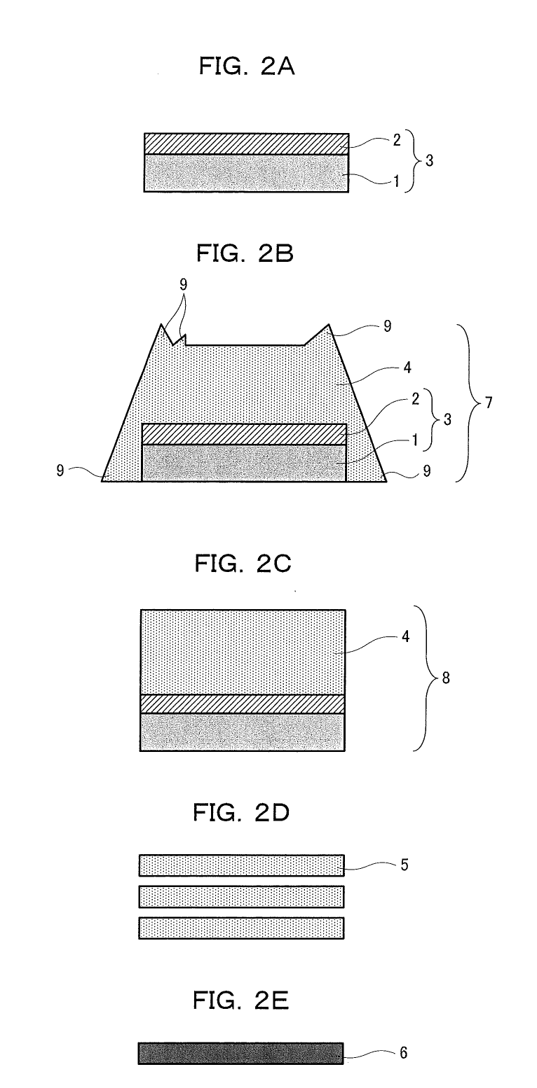

With reference to FIGS. 1 and 2, the method for producing a group III nitride crystal substrate of Embodiment 1 of the present invention is described.

FIG. 1 is a flow chart showing a method for producing the group III nitride crystal substrate of Embodiment 1 of the present invention, and FIGS. 2A to 2E are sectional views illustrating the steps of producing the group III nitride crystal substrate of Embodiment 1.

First, a group III nitride seed crystal substrate 3 is prepared in which, as shown in FIG. 2A, on a base substrate 1 having a C+ plane as the principal plane thereof, a group III nitride seed crystal 2 is beforehand formed as a film in a thickness of 2 μm to 20 μm. As the base substrate 1, any one of the following substrates can be used: a sapphire substrate (crystalline Al₂O₃) C plane, a GaAs substrate in which the surface is a (111) plane, a Si substrate in which the surface is a (111) plane and a SiC substrate in which the surface is a (0001) plane. Alternatively, as the base substrate 1, a self-supporting group III nitride seed crystal substrate may also be used. The group III nitride seed crystal 2 is, for example, a GaN crystal having a thickness of 2 μm to 20 μm. For the growth of the seed crystals of the group III nitrides such as GaN, the vapor phase epitaxial growth method and the liquid phase growth method are used. As the vapor phase epitaxial growth method, the HVPE method (hydride vapor phase epitaxy method) and the MOCVD method (metal organic chemical vapor deposition method) can be used. As the liquid phase growth method, the flux growth method using an alkali metal or the like, the ammonothermal method and the high-temperature high-pressure growth method can be used. Alternatively, as the seed substrate 3, a self-supporting substrate can also be used. In this case, the base substrate 1 can be omitted. Additionally, the plane orientation (principal surface direction) of the seed substrate may be an orientation, other than the (0001) plane orientation, such as the (1-100) plane orientation, the (11-20) plane orientation or the like.

Next, the seed crystal substrate 3 is placed in a crucible as the “seed crystal” for the liquid phase growth and a flux liquid phase growth is performed. The growth of the group III nitride crystal by the flux liquid phase growth method is performed by bringing a melt that includes at least one group III element selected from gallium, aluminum and indium and a flux into contact with the surface of the seed crystal substrate 3 in a nitrogen-containing gas atmosphere, under the conditions that the temperature is set at about 700° C. to 1100° C. and the pressure is set at 30 atm (30×1.013×10⁵ Pa) to 100 atm (100×1.013×10⁵ Pa). As the nitrogen-containing gas, for example, nitrogen gas or ammonia-containing nitrogen gas is used. As the flux, an alkali metal, an alkali earth metal, or a mixture of both of these metals is used. Examples of the alkali metal may include at least one selected from sodium (Na), lithium (Li) and potassium (K), namely, one of these alkali metals or a mixture of these alkali metals. Preferably, sodium (Na) is used. Examples of the alkali earth metal may include calcium (Ca), magnesium (Mg), strontium (Sr) and barium (Ba). Preferably, calcium (Ca), strontium (Sr) and barium (Ba) are used. The alkali earth metals may be used each alone or in combinations of two or more thereof.

When a n-type dopant or a p-type dopant is used in a melt including the above-described at least one group III element selected from gallium, aluminum and indium and an alkali metal, an n-type group III nitride crystal or a p-type group III nitride crystal can be obtained. The dopant amount is adjusted according to the carrier concentration, which is one of the specifications of the semiconductor device. For example, the dopant amount of a gas dopant is adjusted by the gas dopant flow rate. Alternatively, for a solid dopant, an intended mass of the dopant is added to the starting materials for the group III nitride crystal growth (inclusive of the flux). Examples of the group III nitride starting materials may include at least one group III element selected from gallium, aluminum and indium and an intended flux material. Examples of the n-type dopant include Si, O, S, Se, Te and Ge. These may be used each alone or in combinations of two or more thereof. Examples of the p-type dopant include Mg and C. These may also be used each alone or in combinations of two or more thereof.

A group III nitride crystal 4 represented, for example, by the composition formula AlₓGa_{y}In_{1-x-y}N (with the proviso that 0≦x≦1, 0≦y≦1) is formed, as shown in FIG. 2B, so as to enclose the seed crystal substrate 3 by using such an n-type group III nitride crystal or such a p-type group III nitride crystal. The three-dimensional structure on the periphery and the surface of the seed crystal substrate 3 as viewed in FIG. 2B is determined by the growth rate difference depending on the crystallographic orientation.

The step described above is the step shown in FIG. 1 as the crystal growing step 11.

Next, a group III nitride crystal body 7, shown in FIG. 2B, in which the group III nitride crystal 4 is formed is fixed to a jig by adhesion with a wax. Then, the protruding structures 9 formed on the surface and the periphery of the group III nitride crystal body 7 are removed by grinding such as surface grinding and/or cylindrical grinding. Thus, a group III nitride crystal body 8 as shown in FIG. 2C is obtained (the grinding step 12 shown in FIG. 1).

Next, by using a wafer edge grinder, the group III nitride crystal body 8 is subjected to beveling. Then, the group III nitride crystal 4 is sliced in such a way that the thickness of the group III nitride crystal is preferably made to be 200 μm to 800 μm with reference to the underside of the base substrate 1, and thus a group III nitride crystal substrate 5 is obtained (FIG. 2D, the slicing step 13 in FIG. 1). For the slicing step, known cutting devices such as a multi-wire saw, an inner circumference slicer and an outer circumference slicer are used. When the thickness of the group III nitride crystal substrate 5 is thinner than 200 μm, no sufficient strength is obtained. On the other hand, when this thickness is thicker than 800 μm, the number of the produced substrates is made smaller to lead to the increase of the production cost of the group III nitride crystal substrate 5.

Next, for the purpose of removing the asperities of the surface of the group III nitride crystal substrate 5 obtained by slicing, the group III nitride crystal substrate 5 is polished. Specifically, the group III nitride crystal substrate 5 obtained by slicing is fixed by adhesion with a wax to a dummy substrate, the adhered group III nitride crystal substrate 5 is polished in parallel to the surface of the dummy substrate, to a predetermined thickness and to a predetermined surface roughness. Further, the polished group III nitride crystal substrate 5 is mirror-polished by varying the plate material, the load, the rotation number, the abrasive grain size and the like, so as to have a predetermined thickness and a predetermined surface roughness, and thus a group III nitride crystal substrate 6 is obtained (FIG. 2E, the polishing step 14 in FIG. 1).

The surface roughness of the group III nitride crystal substrate 6 on which a semiconductor device such as a light-emitting diode or a laser diode is formed is such that the average roughness Ra (Ra is defined by the arithmetical mean roughness Ra) is preferably 0.1 nm to 5 nm. The Ra smaller than 0.1 nm makes the polishing time correspondingly longer to degrade the productivity. The Ra exceeding 5 nm tends to increase the probability of the occurrence of the short circuit failure responsible for the drop of the open end voltage which is a property of a semiconductor device.

Next, the group III nitride crystal substrate 6 obtained by the polishing step 14 is vertically disposed on a hanger, and is subjected to organic cleaning for the purpose of removing the organic matter such as the waxes used in the slicing step and the polishing step. For the organic cleaning, generally, the organic solvents such as solvent naphtha, acetone, methanol, ethanol and isopropyl alcohol are used in combinations. These organic solvents are used in the order from the lower hydrophilicity to the higher hydrophilicity. For example, organic cleaning is performed in the order of solvent naphtha, acetone and isopropyl alcohol. Then, for the purpose of removing the organic components, cleaning with sulfuric acid-hydrogen peroxide mixture is performed; and furthermore, for the purpose of removing the oxide layer of the substrate, a buffer hydrofluoric acid treatment is performed. Here, the above-described step is referred to as the first cleaning step 15 as shown in FIG. 1.

Next, the group III nitride crystal substrate 6 is subjected to a heat treatment (the heat treating step 16 in FIG. 1). The group III nitride crystal substrate 6 is placed in a quartz tube in a manner leaning against a quartz boat. Before the heat treating step, for the purpose of reducing the moisture and the impurity gases such as oxygen in the furnace, a vacuum gas purge is performed at least three times. The vacuum gas purge as referred to herein means an operation in which the pressure inside the furnace is reduced to a pressure of −99 kPa or lower, and then the pressure inside the furnace is made to be 1 atm (1×1.013×10⁵ Pa) with a nitrogen-containing gas. After the vacuum gas purge, the heat treatment is performed. The heat treatment is performed in an atmosphere in which the nitrogen-containing gas such as either one of nitrogen gas and ammonia gas or a mixed gas composed of both of these gases has a predetermined flow rate and a pressure of 1 atm. The heat treatment temperature is set at a temperature equal to or higher than the lowest temperature (boiling point) at which the above-described flux is vaporized and equal to or lower than the highest temperature at which the surface of the group III nitride crystal substrate 6 is not decomposed.

The reasons for the fact that nitrogen is essential for the atmospheric gas are that as the atmosphere runs short of nitrogen, the nitrogen constituting the crystal is dissociated and hence the crystal undergoes nitrogen deficit to degrade the crystal quality and at the same time the group III nitride crystal is decomposed. The predetermined nitrogen gas flow rate is preferably such that the nitrogen gas flow speed is 0.1 m/min to 10 m/min. When the nitrogen gas flow speed is less than 0.1 m/min, the nitrogen dissociation occurs. On the other hand, when the nitrogen gas flow speed exceeds 10 m/min, the decomposition of the group III nitride crystal is promoted.

The heat treatment temperature is described in detail. The temperature equal to or higher than the lowest temperature at which the flux is vaporized and equal to or lower than the highest temperature at which the surface of the group III nitride crystal substrate 6 is not decomposed means, when potassium is mainly used as the flux, a temperature equal to or higher than the vaporization temperature (boiling point) of potassium, namely, 774° C. and equal to or lower than 1200° C. at which the decomposition of the surface of the group III nitride crystal substrate 6 occurs. When sodium is used as the flux, the temperature concerned is equal to or higher than the vaporization temperature (boiling point) of sodium, namely, 883° C. and equal to or lower than 1200° C.

The heat treatment time is varied depending on the heat treatment temperature, the epitaxial growth temperature, the epitaxial growth time and the like, and is for example about 1 hour to 5 hours.

The vaporization of the flux enables the effective diffusion of the flux present in the vicinity of the surface of the group III nitride crystal substrate 6 so as to exert adverse effects, and enables the flux to be deposited on the surface of the group III nitride crystal substrate 6. In other words, the flux remaining inside the group III nitride crystal substrate 6 can be discharged to outside the substrate 6. The vaporization of the flux into gas increases the diffusion coefficient by a factor of a few tens or more as compared to the diffusion coefficient in the liquid state. Therefore, the flux gas can effectively diffuse to the surface of the crystal substrate 6. The flux to exert adverse effects at the time of the epitaxial growth means the fluxes present in the defects such as the crystal grain boundaries and the inclusions in the vicinity of the surface of the crystal substrate 6. These fluxes are vaporized at the time of the epitaxial growth to cause the crystal surface roughening and the crystal exfoliation. The fluxes other than the fluxes present in the defects hardly diffuse even at the epitaxial growth temperature. Therefore, the sodium flux atomic concentration actually measured in the normal portions obtained by the heat treatment performed under the above-described conditions can be made to be equal to or less than the limit level of the detection level of the secondary ion mass spectrometer, namely, 2×10¹⁴ atoms/cm³.

As described above, the group III nitride crystal 4 is sliced into a wafer shape to form the group III nitride crystal substrate 6, and then before the epitaxial growth treatment, as a device forming step, the heat treatment is performed at a temperature equal to or higher than the lowest temperature capable of vaporizing the flux and lower than the highest temperature at which the surface of the group III nitride crystal substrate 6 is not decomposed, and thus the flux in the vicinity of the surface of the group III nitride crystal substrate 6 can be removed by vaporization, and hence the failures due to the presence of the flux at the time of the epitaxial growth can be suppressed.

Finally, for the purpose of removing the by-products produced by the heat treating step 16, the group III nitride crystal substrate 6 is subjected to a cleaning treatment (the second cleaning step 17 in FIG. 1). Examples of the cleaning treatment include purified water cleaning and acid solution cleaning. As the acid solution, a hydrofluoric acid solution, a buffer hydrofluoric acid solution, a hydrochloric acid solution, a sulfuric acid solution and a sulfuric acid-hydrogen peroxide mixture can be used. For example, the group III nitride crystal substrate 6 after the heat treatment is immersed for 10 minutes in a 3% concentration buffer hydrofluoric acid solution diluted with purified water (49% HF aqueous solution:40% NH₄F aqueous solution=7:1), successively subjected to running purified water cleaning for 10 minutes, and then dried with nitrogen. Subsequently, the group III nitride crystal substrate 6 is further immersed for 10 minutes in a sulfuric acid-hydrogen peroxide mixture (98% sulfuric acid:30% hydrogen peroxide solution=4:1) set at 100° C. to 120° C., successively subjected to running purified water cleaning for 10 minutes, and then dried with nitrogen.

The second cleaning step 17 as described above enables the production of the group III nitride crystal substrate in which the sodium flux atomic concentration in the vicinity of the surface of the crystal substrate as evaluated with the secondary ion mass spectrometry is lower than the flux atomic concentration inside the substrate and is for example 2×10¹⁴ atoms/cm³, which is close to the detection limit level of the secondary ion mass spectrometer.

### Embodiment 2

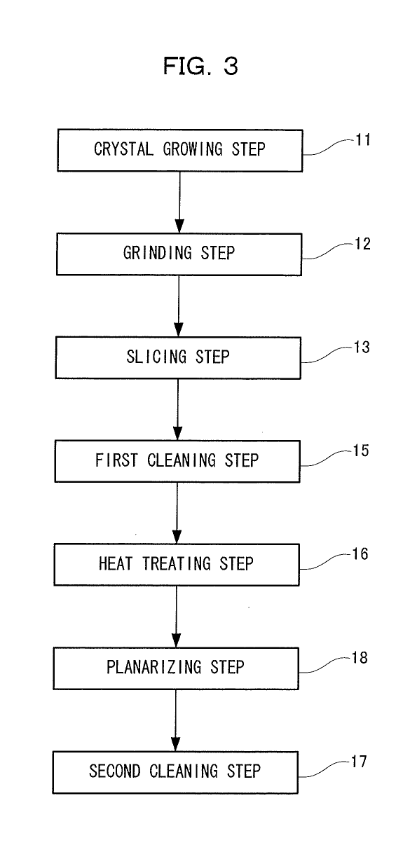

Next, with reference to FIG. 3, the method for producing a group III nitride crystal substrate of Embodiment 2 of the present invention is described.

The method for producing a group III nitride crystal substrate of Embodiment 2 is approximately the same as the above-described production method of Embodiment 1 as far as the heat treating step 16, with omission of the polishing step. The essential difference from Embodiment 1 resides in that by adding a step of improving the surface nature degradation caused by the heat treatment, the production yield of the finally obtained semiconductor device is improved.

FIG. 3 is a flow chart showing the method for producing a group III nitride crystal substrate of Embodiment 2 of the present invention. As described above, the crystal growing step 11 to the heat treating step 16 in FIG. 3 are approximately the same steps as the crystal growing step 11 to the heat treating step 16 in FIG. 1. As described above, however, the polishing step 14 before the heat treatment shown in FIG. 1 can be omitted. In the method for producing a group III nitride crystal substrate of Embodiment 2 of FIG. 3, polishing is performed in the below-described planarizing step 18.

Present Embodiment 2 is characterized in that when the surface nature of the substrate is degraded by the discharge of the flux gas from the substrate in the heat treating step 16, the planarizing step 18 is performed subsequently to the heat treating step 16.

Specifically, when the group III nitride crystal substrate is heat treated for discharging the flux, the nitrogen concentration on the surface of the group III nitride crystal substrate is concomitantly decreased to form asperities on the surface of the crystal substrate. In present Embodiment 2, the thus formed asperities are removed by the planarization to improve the surface nature of the group III nitride crystal substrate.

As shown in FIG. 3, first, as in Embodiment 1, the steps to the heat treating step 16 are performed, and subsequently the above-described surface roughness Ra of the crystal substrate is measured. When the surface roughness Ra exceeds, for example, 5 nm for the surface to be rough, the planarizing step 18 is performed after the heat treating step 16 as shown in FIG. 3. Subsequently, the second cleaning step 17 is performed, and thus the group III nitride crystal substrate usable for the epitaxial growth at the time of forming an element can be obtained.

The planarizing step 18 is described in detail. First, under the condition that the group III nitride crystal substrate is mounted on a dummy substrate, the asperities of the surface of the group III nitride crystal substrate are removed by performing an operation such as a mechanical polishing of the surface of the group III nitride crystal substrate. Then, the dummy substrate is detached, and the wax used for the adhesion of the group III nitride crystal substrate is removed in the same manner as in the first cleaning step 15. Further, a polishing-modified layer is produced by the mechanical polishing or the like, and hence the surface of the group III nitride crystal substrate is planarized by removing the polishing-modified layer by applying a plasma dry etching with a chlorine-based gas.

Examples of the planarizing technique other than the above-described mechanical polishing may include wet etching with a buffer hydrofluoric acid solution, a hydrochloric acid solution and a sulfuric acid-hydrogen peroxide mixture. Alternatively, the planarization can be performed by a mechanochemical polishing that is a combination of polishing and wet etching. The mechanochemical polishing can be performed by using, for example, colloidal silica as an abrasive grain, and by selecting the hydrogen ion index (pH), the pad, the load and the rotation number as predetermined.

The targeted level of the planarization is such that the surface roughness is made not to affect the device, and in other words the surface roughness Ra is preferably made to be 5 nm or less.

Then, after the polishing of the group III nitride crystal substrate, the dummy substrate is detached from the group III nitride crystal substrate. Subsequently, for the purpose of removing the wax used for the adhesion of the group III nitride crystal substrate, cleaning is performed in the same manner as in the first cleaning step 15, and further, for the purpose of removing the ion damages suffered at the time of the plasma dry etching, the second cleaning step 17 is performed in the same manner as in Embodiment 1, and thus the group III nitride crystal substrate can be provided.

For the purpose of removing the group III nitride having a low nitrogen concentration, produced in the heat treating step as described above, on the surface of the group III nitride crystal substrate, the substrate surface is planarized after the heat treating step, and hence the surface nature of the group III nitride crystal substrate can be ensured, in addition to the fact that the failure due to the flux, at the time of the epitaxial growth can be suppressed by removing through vaporization the flux in the vicinity of the surface of the group III nitride crystal substrate.

It is to be noted that the planarizing step 18 can be performed, as described above, after the heat treating step 16 and before the second cleaning step 17; however, the planarizing step 18 may also be performed at the same time as the second cleaning step 17 or after the second cleaning step 17, as the case may be.

### Embodiment 3

In above-described Embodiments 1 and 2, the flux solution growth method using an alkali metal as the flux is used. On the other hand, the heat treating step characterizing the present invention can also be applied to a method for producing a group III nitride crystal substrate using the ammonothermal method, as Embodiment 3.

In the ammonothermal method, the gallium nitride crystal is precipitated in ammonia being a supercritical fluid, and hence liquid ammonia is confined inside the produced group III nitride crystal substrate as the case may be. By performing a heat treating step, the liquid ammonia can be vaporized to be discharged to outside the crystal.

The heat treatment temperature required for this purpose is about 1000° C. to 1200° C. Additionally, it is necessary to set the heat treatment temperature at a temperature equal to or lower than 1200° C. that is the limit at or below which no decomposition occurs on the surface of the group III nitride crystal substrate. It is to be noted that the boiling point of ammonia under atmospheric pressure is −33° C., but heating to about 1000° C. or higher is required, as described above, for the purpose of discharging ammonia as in the gasified state to outside the crystal substrate, on the basis of the present invention.

In the ammonothermal method, a mineralizer is used as the case may be, for the purpose of increasing the dissolved amount of gallium or gallium nitride in ammonia being a supercritical fluid. In this case, there is a possibility that not only ammonia but also the mineralizer is confined in the obtained crystal substrate. When the heat treatment is performed on the basis of the present invention, the mineralizer can also be discharged together with ammonia to outside the crystal substrate, and hence the failure at the time of epitaxial growth, due to the remaining mineralizer can be suppressed.

Next, Examples of the method for producing a group III nitride crystal substrate of the present invention are described.

In following Examples, the flux solution growth using an alkali metal as the flux is described. However, also in the case of the group III nitride crystal produced by using the ammonothermal method, by applying following Examples in the same manner as described above, the impurities inside the crystal can be removed.

In following Examples, Na was used as the alkali metal, and the case where the group III nitride crystal is a GaN crystal is described. However, the present invention can also be applied to other group III nitride crystals such as AlN, AlGaN, GaInN and AlGaInN.

### Example 1

The process for producing the GaN substrate, as a group III nitride crystal substrate, on the basis of the method illustrated in FIGS. 1 and 2 is described as an example.

First, as shown in FIG. 2A, a GaN seed crystal was formed as a group III nitride seed crystal 2 on a base substrate 1, by the MOCVD method. For the base substrate 1, the sapphire (crystalline Al₂O₃) (0001) C plane was used. Specifically, the base substrate 1 was heated to about 1020° C. to 1100° C., trimethylgallium (TMG) and NH₃ were fed onto the base substrate 1, and thus the seed crystal 2 composed of gallium nitride (GaN) was formed in a film thickness of 10 μm. The GaN seed crystal substrate, as a group III nitride seed crystal substrate 3, was composed of the base substrate 1 and the seed crystal 2.

Next, as shown in FIG. 2B, a GaN crystal, as a group III nitride crystal 4, was grown on the seed crystal 2 (the crystal growing step 11 in FIG. 1) by using the flux liquid phase growth method. Hereinafter, an example of the flux liquid phase growth method is described in detail.

First, Ga, Na, an alkali metal, as the flux, and Ge as an n-type dopant, were weighed out in specified amounts (for example, Ga:Na:Ge (molar ratio)=0.25:0.71:0.04), and were set in a crucible together with the GaN seed crystal substrate, as the group III nitride seed crystal substrate 3. Next, the crucible was placed in a crystal growth vessel, and maintained at 800° C. inside the vessel to thereby convert the contents in the crucible into a liquid phase; while the temperature and the pressure were being maintained to be constant in a nitrogen gas atmosphere under a pressure of 40 atm (40×1.013×10⁵ Pa), the liquid phase growth was performed for 96 hours to yield the reaction products including a GaN crystal.

Next, the crystal growth vessel was cooled back to the room temperature, the contents of the crucible were converted into a solid phase, and the crucible was taken out from the vessel. Then, ethanol was placed in the crucible, the ethanol and the solid flux covering the reaction products including the GaN crystal were reacted with each other, and thus the flux was removed from around the reaction products. Further, the reaction products were subjected to an ultrasonic cleaning with purified water, and thus a GaN crystal body, as the group III nitride crystal body 7 shown in FIG. 2B, was obtained. The GaN crystal body had protruding structures 9 on the periphery of the seed crystal and on the periphery and the surface of the crystal body, due to the crystal orientations and the differences in the shapes in the crystal planes and in the peripheries of the crystals. In this way, the GaN crystal body, as the group III nitride crystal body 7, was produced by the flux liquid phase growth method.

Next, the GaN crystal body was fixed to a dummy substrate with a wax by thermal adhesion and the protruding structures 9 were removed by cylindrical grinding (FIG. 2C, the grinding step 12 in FIG. 1).

Then, the substrate was subjected to beveling with a wafer edge grinder, and the GaN crystal was sliced (cut) with a multi-wire saw with reference to the underside of the base substrate 1 so as to have a substrate thickness of 400 μm to 600 μm, to yield a GaN substrate, as a group III nitride seed crystal substrate 5 (FIG. 2D, the slicing step 13 in FIG. 1).

Subsequently, the sliced GaN substrate was thermally adhered with a wax to a dummy substrate, and then the GaN substrate, as the group III nitride seed crystal substrate 5, was polished with a polishing apparatus with reference to the underside of the base substrate 1. By this polishing, the sliced GaN substrate was subjected to parallel flattening to result in the substrate thickness of 400 μm±40 μm. Further, the parallel-flattened substrate was mirror-polished with a single side polishing apparatus, by varying the plate material, the load, the number of rotation and the abrasive grain size to yield a GaN substrate, as the group III nitride seed crystal substrate 6 in which the Ga-surface roughness Ra of the GaN substrate was equal to or less than 1 nm (FIG. 2E, the polishing step 14 in FIG. 1).

Subsequently, for the purpose of removing the wax used for fixing the GaN substrate to the dummy substrate, organic cleaning was performed. For the organic cleaning, solvent naphtha (registered trademark), acetone, isopropyl alcohol and the like were used. Further, for the purpose of removing the heavy metals and the organic matter on the GaN substrate, the GaN substrate was chemically etched with a concentrated sulfuric acid-containing solution. Additionally, for the purpose of removing the oxide layer of the GaN substrate, the GaN substrate was treated with buffer hydrofluoric acid and dried with nitrogen (the first cleaning step 15 in FIG. 1).

Next, the GaN substrate was heat treated (the heat treating step 16 in FIG. 1). First, under the condition that the GaN substrate was placed in a quartz tube in a manner leaning against a quartz boat, for the purpose of reducing the moisture and the impurity gases such as oxygen in the furnace, a vacuum purge was performed three times. Specifically, the following set of operations was repeated three times: the pressure inside the furnace was reduced to a pressure of −99 kPa or lower, and then the pressure inside the furnace was made to be 1 atm (1×1.013×10⁵ Pa) by feeding dry nitrogen into the furnace. Next, while dry nitrogen was being made to flow at a flow rate of 1 L/min (flow speed: 46 cm/min) and the pressure inside the furnace was being made to be 1 atm (1×1.013×10⁵ Pa), the temperature was increased to 800° C. at a temperature increase rate of 200° C./hr. Then, the temperature was maintained at 800° C. for 30 minutes, and thus the temperature of the GaN substrate was made uniform. Successively, the temperature was increased over 30 minutes to the heat treatment temperature of 900° C., and then the temperature inside the furnace was maintained at 900° C. for 90 minutes to perform the heat treatment. Then, the temperature was decreased to room temperature at a rate of 200° C./hr.

Finally, the GaN substrate after the heat treatment was immersed in the buffer hydrofluoric acid solution for 10 minutes, successively immersed in the sulfuric acid-hydrogen peroxide mixture set at 120° C. for 10 minutes, successively subjected to running purified water cleaning for 10 minutes, and then dried with nitrogen to produce a GaN substrate capable of forming a semiconductor element (the second cleaning step 17 in FIG. 1).

As described above, after the group III nitride crystal substrate was formed by slicing the group III nitride crystal into a wafer shape and before the epitaxial growth treatment, as an element forming step, the heat treatment was performed at a temperature equal to or higher than the lowest temperature capable of vaporizing the flux and lower than the highest temperature at which the surface of the group III nitride crystal substrate was not decomposed, and thus the flux in the vicinity of the surface of the group III nitride crystal substrate was able to be removed by vaporization. Consequently, the failure due to the flux at the time of the epitaxial growth was able to be suppressed.

Here, the case where the heat treatment temperature was set at 900° C. has been described; however, the heat treatment temperature was also able to be set at, for example, 1000° C. or 1100° C.

### Comparative Example 1

As compared to Example 1, the heat treatment temperature was altered to 800° C., a temperature lower than the lowest temperature capable of vaporizing the flux. The steps other than the heat treating step were performed in the same manner as in Example 1, and a GaN substrate was produced. The evaluation results of the GaN substrate are described below.

### Example 2

With reference to FIG. 3, the method for producing a group III nitride crystal substrate of Example 2 is described by taking a GaN substrate as an example.

Under the conditions that the heat treatment temperature was set at 1200° C., ammonia gas was made to flow at a flow rate of 1 L/min (flow speed: 46 cm), and the pressure inside the furnace was set at 1 atm (1×1.013×10⁵ Pa), the heat treatment was performed for 2 hours, and thus, as described below, asperities were formed on the surface of the GaN substrate after the heat treatment. Accordingly, in present Example, the improvement of the surface asperities was attempted by the below-described “planarization.”

As shown in FIG. 3, for the purpose of removing the asperities on the substrate surface formed by the heat treatment, the “planarizing step 18” was performed. It is to be noted that the steps as far as the heat treating step 16 were the same as the corresponding steps in the flow chart of Example 1 shown in FIG. 1.

As the “planarizing step 18,” the surface of the substrate was subjected to mechanical polishing or the like, the substrate was cleaned to remove the wax used for the polishing, and the substrate was subjected to a plasma dry etching using chlorine gas for the purpose of removing the polishing-modified layer produced by the mechanical polishing or the like. Finally, the “second cleaning step 17” was performed in the same manner as in Example 1, and thus the GaN substrate, as the group III nitride crystal substrate, was obtained.

As described above, for the purpose of removing the asperities, on the surface of the group III nitride crystal substrate, produced by the heat treating step, in other words, for the purpose of removing the group III nitride, low in the nitrogen concentration, on the crystal substrate, the planarizing step 18 of planarizing the surface of the group III nitride crystal substrate was performed after the heat treating step 16. In this way, the surface nature of the group III nitride crystal substrate was able to be ensured, in addition to the fact that the failure due to the flux, at the time of the epitaxial growth was able to be suppressed by removing through vaporization the flux in the vicinity of the surface of the group III nitride crystal substrate.

### Comparative Example 2

As compared to Example 2, the heat treatment temperature was altered to 1300° C., a temperature higher than the limit where decomposition occurred on the surface of the group III nitride crystal substrate. The steps other than the heat treating step were performed in the same manner as in Example 2, and a GaN substrate was produced.

Hereinafter, description is made on the results of the evaluations performed on the GaN substrates, being each an example of the group III nitride crystal substrate, produced in above-described Example 1, Comparative Example 1, Example 2 and Comparative Example 2.

Here, the surface condition of a substrate after the heat treatment was evaluated in terms of the surface roughness Ra after the heat treatment and the macro-defect area ratio after the heat treatment. The flux atomic concentration was evaluated by the secondary ion mass spectrometry measurement.

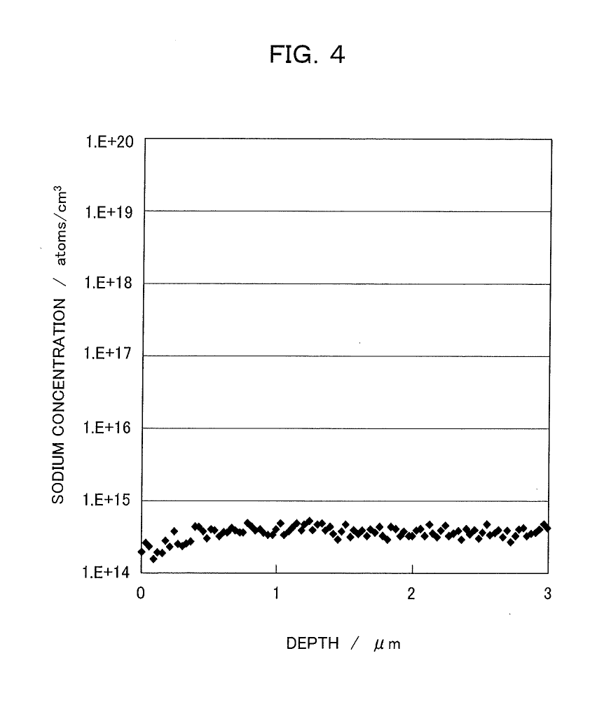

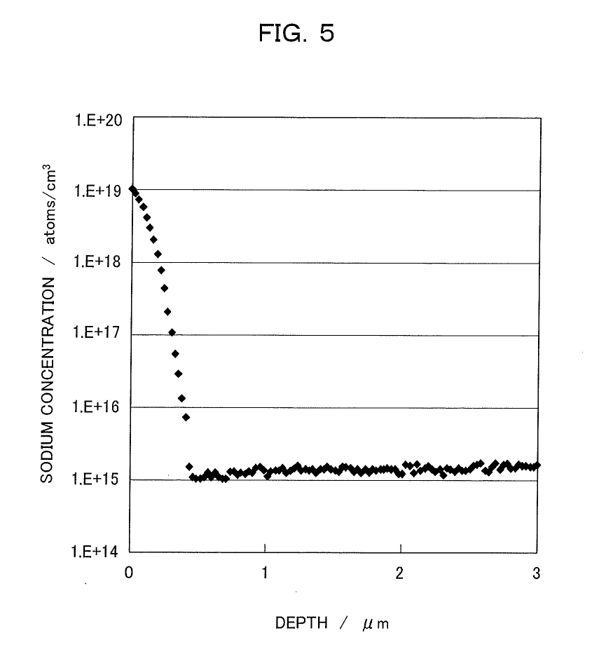

The evaluation results of Examples 1 and 2 and Comparative Examples 1 and 2 are described with reference to FIGS. 4 and 5 and Table 1.

FIG. 4 is a graph showing the results of the secondary ion mass spectrometry measurement for the case of the heat treatment temperature of 900° C. in Example 1, and FIG. 5 is a graph showing the results of the secondary ion mass spectrometry measurement for the case of the heat treatment temperature of 800° C. in Comparative Example 1. Table 1 shows the evaluation results of the group III nitride crystal substrates.

TABLE 1

| | Heat treatment (annealing) | | | | | |
|---|---|---|---|---|---|---|
| | temperature [° C.] | | | | | |
| | 800 | 900 | 1000 | 1100 | 1200 | 1300 |
| Surface roughness | G | G | G | G | A | P |
| Ra of Ga-surface | | | | | | |
| (after heat | | | | | | |
| treatment) | | | | | | |
| Macro-defect area | G | G | G | G | A | P |
| ratio (after heat | | | | | | |
| treatment) | | | | | | |
| Surface roughness | A | G | G | G | *G | — |
| Ra of Ga-surface | | | | | | |
| (after epitaxial | | | | | | |
| growth) | | | | | | |
| Macro-defect area | P | G | G | G | *G | — |
| ratio (after | | | | | | |
| epitaxial growth) | | | | | | |

*Planarization was performed.
—: No evaluation was made.

The surface roughness was measured with a surface roughness tester ZYGO (registered trademark), and was represented by the surface roughness Ra (here, Ra is defined by the “arithmetical mean roughness Ra”) of the Ga-surface of the GaN substrate. First, the surface roughness Ra after the heat treatment was measured, and thus the surface condition depending on the heat treatment conditions was evaluated. Further, as the evaluation standards for the surface roughness Ra, from the viewpoint whether usable or not for the epitaxial growth at the time of element formation, the case where the surface condition was satisfactory was marked with “G (Good)”, the case where the surface condition was usable was marked with “A (Average)” and the case where the surface condition was not usable was marked with “P (Poor)”. Here, the case of “G” is the case where the surface roughness Ra after the heat treatment is 5 nm or less. A substrate marked with “G” can be used for the production of a semiconductor device after the second cleaning step as in Example 1. The case of “A” is the case where the surface roughness Ra after the heat treatment exceeds 5 nm and is 10 nm or less. In this case, as in Example 2, the planarization of the substrate is preferably performed. By performing the planarizing step and the second cleaning step, the substrate can be used for the production of a semiconductor device. The case of “P” is the case where the surface roughness Ra after the heat treatment exceeds 10 nm. The case of “P” where Ra exceeds 10 nm is, as compared to the usable case of “A”, required to regulate the operations and the time period of the planarizing step, hence the step comes to be complicated to degrade the productivity, and the case of “P” is not usable.

The macro-defect area ratio is described. The “macro-defect” was defined as the defect discernible at an observation magnification of 50 by using an optical microscope with an objective lens having a magnification of 5. Specifically, the observed image obtained with an observation magnification of 50 was subjected to an image analysis to extract the macro-defects, and the evaluation was performed in terms of the area ratio (%) of the macro-defects to the total observation area. Examples of the macro-defects include voids, foreign substances, crystal grain boundaries, cracks and a secondary crystal phase (a crystal phase other than the primary crystal phase). As compared to the clean areas, these defects are different in the factors such as the optical transmittance, the optical reflectance and the optical phase difference, and hence these defects are discernible from the normal clean areas by the observation with an optical microscope. Here, the observation was performed in the light transmission mode, the obtained observation image was binarized, the defect area was obtained as the total areas of the individual defects, and the ratio of the defect area to the whole observation area was derived as the defect area ratio (%). The evaluation standards for the macro-defect area are as follows: first the central area of the substrate is defined by excluding the area extending from the peripheral edge of the substrate to the location 2 mm inwardly away from the edge; the case where the defect area ratio is 1% or less in the central area is marked with “G (Good)”; the case where the macro-defect area ratio exceeds 1% and is 50 or less in the central area is marked with “A (Average)”; and the case where the macro-defect area ratio exceeds 5% in the central area is marked with “P (Poor)”. A substrate marked with “G” can be used for the production of a semiconductor device after the second cleaning step as in Example 1. A substrate marked with “A” can be used for the production of a semiconductor device by performing the planarizing step and the second cleaning step as in Example 2. A substrate marked with “P” is, as compared to the usable substrate marked with “A”, required to regulate the operations and the time period of the planarizing step, hence the step comes to be complicated, and hence even when an epitaxial film is grown to produce a device by using this GaN substrate, the production yield comes to be low.

The surface nature after the epitaxial film growth was evaluated similarly in terms of the surface roughness Ra and the macro-defect area ratio of the epitaxial film, after the epitaxial film was grown under the below-described conditions. The evaluation standards for the surface nature are the same as described above.

The conditions under which the epitaxial film was grown are described. When the epitaxial film was grown, the MOCVD growth method was used, the substrate temperature was set at 1050° C., TMG (trimethylgallium) gas and NH₃ (ammonia) gas were used as the main component gases, SiH₄ (silane) gas was used as the dopant gas, and thus a Si-doped n-type GaN layer having an n-type carrier concentration of 5×10¹⁸ cm⁻³ to 1×10¹⁹ cm⁻³ was formed as a 2-μm thick film on the GaN substrate.

The secondary ion mass spectrometry measurement used for the measurement of the flux atomic concentration is described. The Na⁺ ion atomic concentration (atoms/cm³) was analyzed by using CAMECA (registered trademark) -ims, under the measurement conditions that the primary ion was O₂⁺, the primary ion energy was 8.0 keV, the primary ion current was 140 nA and the analysis area diameter was 60 μm, while the etching was being performed from the GaN substrate surface to the depth of a few micrometers. The Na⁺ atomic concentration, in the region from the substrate surface to the depth of at least 3 μm, is preferably 1×10¹⁵ atoms/cm³ or less, and more preferably equal to or less than 2×10¹⁴ atoms/cm³, the detection limit of the secondary ion mass spectrometry measurement under the above-described measurement conditions. The Na⁺ ion atomic concentration exceeding 1×10¹⁵ atoms/cm³ in the region from the substrate surface to the depth of 3 μm offers a factor to cause short-circuiting in the semiconductor device and thus affects the performances of the device.

It is to be noted that the above-described examination of various properties can be performed in the practical production steps as an examination step in the same manner as described above. This examination step is preferably performed after the heat treating step 16.

As shown in Table 1, Example 1, Comparative Example 1, Example 2 and Comparative Example 2 were classified according to the heat treatment temperature, namely, the annealing temperature; the cases the heat treatment temperatures of which were set respectively at 800° C., 900° C., 1000° C., 1100° C., 1200° C. and 1300° C. were evaluated. The evaluation results are as follows.

(The Case of the Heat Treatment Temperature of 900° C.)

The surface roughness Ra of the Ga-surface of the GaN substrate produced under this temperature condition was measured to be Ra=0.6 nm so as to be marked with “G”. Additionally, the macro-defect area ratio after the heat treatment was found to be 0.03% so as to be marked with “G”.

As is clear from FIG. 4 showing the results of the secondary ion mass spectrometry measurement, the Na⁺ atomic concentration had a lower value on the surface of the GaN substrate than inside the substrate. This is because the Na remaining on the surface of the substrate had been discharged to outside the substrate by the heat treatment. Specifically, the Na⁺ atomic concentration was 2×10¹⁴ atoms/cm³ on the surface of the GaN substrate, was slightly increased from the surface to the depth of 0.3 μm, was saturated at the depth of 0.3 μm or more to be constant at 3×10¹⁴ atoms/cm³.

After the growth of the epitaxial film, the surface condition of the GaN substrate was evaluated in terms of the surface roughness Ra and the macro-defect area ratio. The surface roughness Ra of the epitaxial film after the epitaxial growth was somewhat increased, but was 1 nm to be marked with “G”. On the other hand, the macro-defect area ratio remained unchanged from the surface condition before the epitaxial growth, to be marked with “G”. Additionally, the secondary ion mass spectrometry measurement was performed to find the following: the Na⁺ atomic concentration in the region from the vicinity of the interface between the epitaxial film and the GaN crystal substrate to the inside of the GaN substrate was, in the same manner as before the epitaxial film growth, such that the Na⁺ atomic concentration was small in the interface between the epitaxial film and the GaN substrate, was slightly increased as far as the depth in the GaN substrate was increased to be 0.3 μm, and was saturated at a depth of 0.3 μm or more to be constant at 3×10¹⁴ atoms/cm³.

(The Case of the Heat Treatment Temperature of 800° C.)

The surface roughness Ra=0.5 nm and the macro-defect area ratio 0.003% after the heat treatment at 800° C. were both satisfactory to be both marked with “G.”

However, after the epitaxial growth, the surface roughness Ra of the epitaxial film was 6.0 nm to be marked with “A”. Additionally, the macro-defects on the epitaxial film surface were increased, and consequently the macro-defect area ratio was found to be 5.6% so as to be marked with “P”. The macro-defective portions were recessed in shape (hereinafter, referred to as “pit shape”), and recessed portions having a maximum depth of a few hundreds nanometers were found to occur. The secondary ion mass spectrometry of the macro-defective portions was performed in the region from the vicinity of the interface between the epitaxial film and the GaN crystal to the inside of the GaN substrate, and found an abnormal deposition of sodium (Na), the flux component, in the macro-defective portions inside the GaN substrate.

FIG. 5 shows the results of the secondary ion mass spectrometry of the Na⁺ atomic concentration in the region from the interface between the epitaxial film and the GaN substrate to the inside of the GaN substrate, under this temperature condition. Due to the epitaxial growth, the abnormal deposition of Na⁺ atoms was found in the interface between the epitaxial film and the GaN substrate, and the Na⁺ atomic concentration in the vicinity of the interface was increased to be as high as 1×10¹⁹ atoms/cm³. On going from the interface deep into the inside of the GaN crystal substrate, the Na⁺ atomic concentration was abruptly decreased, exhibited a saturation tendency at the depth of 500 nm from the interface, and came to be an approximately constant value. In other words, the Na⁺ atomic concentration at the depth of 500 nm from the interface exhibited a somewhat higher value of 1×10¹⁵ atoms/cm³ as compared to the Na⁺ atomic concentration inside the GaN substrate in the case of the heat treatment temperature of 900° C. in Example 1. This is because, at the time of the O₂⁺ ion etching, Na⁺ ions reattached to around the measurement region and then detached. In this case, the Na⁺ ion offers a factor to cause short-circuiting failure in the semiconductor device such as a laser diode or a light-emitting diode formed with the epitaxial film, and thus adversely affects the performances of the device. Additionally, the light output is disadvantageously degraded as far as the long-term reliability is concerned.

The abnormal deposition of Na occurring after the epitaxial growth in the case of the heat treatment temperature of 800° C. is ascribable to the fact that the heat treatment temperature was lower than the Na vaporization temperature of 883° C., and hence the discharge of Na from the substrate through gasification was not able to be performed. This abnormal deposition is also ascribable to the fact that the epitaxial growth temperature (1050° C. to 1100° C.) was higher than the Na vaporization temperature of 883° C., and consequently the gasification of Na and the deposition of Na on the substrate surface occurred at the time of epitaxial growth. When at the time of the growth of GaN in the sodium flux liquid phase, the Na contained in the defective portions in the vicinity of the surface of the GaN substrate undergoes the change of state from liquid to gas, the internal stress is generated with an increasing factor of about 1000. The tensile strength of the normal portion of the GaN substrate is 67 GPa, and is larger by a factor of about 2 than the internal stress due to the vaporization of the flux although depending on the flux amount. Accordingly, the generated internal stress does not adversely affect the epitaxial film. However, the defective portions of the GaN substrate are small in tensile strength, and hence the internal stress due to the vaporization of the flux exceeds the tensile strength of the defective portions, as the case may be. In such a case, the surface of the GaN substrate is roughened and exfoliated to adversely affect the epitaxial film grown on the GaN substrate.

As described above, the evaluation results after the production of the GaN substrate were satisfactory. However, subsequently, due to the heat at the time of the epitaxial growth for the formation of an element, the Na used as the flux was deposited on the surface of the GaN substrate to offer causes for failures. In other words, when the heat treatment temperature at the time of the production of the substrate was set at 800° C., the flux was deposited at the time of the formation of an element. Consequently, it has been revealed that when a sodium-based flux is used at the time of the growth of a crystal, the subsequent heat treatment temperature of 800° C. cannot be adopted.

(The Case of the Heat Treatment Temperature of 1000° C.)

When the heat treatment at 1000° C. was performed in Example 1, the surface roughness Ra of the Ga-surface was increased to be 1.3 nm (“G”). The macro-defect area ratio after the heat treatment was 0.01% (“G”); an observation with an electron microscope at a magnification of 1000 identified the balloon-shaped (droplet-shaped) defects formed by the deposition of Ga on the surface and pit-shaped defects. When the epitaxial growth on the GaN substrate was subsequently performed, the surface roughness Ra was the same as the surface roughness before the growth of the epitaxial film, namely, Ra=1.3 nm to be marked with “G”, and no increase of the macro-defects was identified and the macro-defect area ratio remained to be 0.01% to be marked with “G”.

In other words, when the heat treatment temperature was set at 1000° C. in Example 1, no abnormalities were found in the epitaxial film on the GaN substrate after the epitaxial growth. Consequently, it was verified that by setting the heat treatment temperature at 1000° C. in Example 1, the sodium (Na), the flux component, was able to be effectively removed.

(The case of the heat treatment temperature of 1100° C.)

When the heat treatment at 1100° C. was performed, the surface roughness Ra of the Ga-surface of the GaN substrate was 1.5 nm (“G”). The macro-defect area ratio immediately after the heat treatment was 0.15% to be marked with “G”, and the pit-shaped defects predominated the balloon-shaped defects. When the epitaxial film growth on the GaN substrate was subsequently performed, no increase of the surface roughness Ra and no increase of the macro-defects were found (both of the surface roughness and the macro-defect area ratio were marked with “G”). Consequently, it was verified that by setting the heat treatment temperature at 1100° C. in Example 1, the sodium (Na), the flux component, was able to be effectively removed.

(The Case of the Heat Treatment Temperature of 1200° C.)

When the heat treatment was performed at 1200° C., the surface roughness Ra of the Ga-surface of the GaN substrate was 8.3 nm (“A”), and the macro-defect area ratio of the GaN substrate was 1.3% (“A”). Because the Ra exceeding 5 nm exerts adverse effects at the time of the growth of the epitaxial film, according to the prescriptions of Embodiment 2, the “planarization” was performed after the heat treating step, in such a way that the polishing amount was 1 μm or less. To this planarizing step, a mirror polishing using a diamond slurry having an average diameter of 50 nm was applied. After the polishing, the dummy substrate was detached, and for the purpose of removing the wax used for adhesion, a cleaning step (the same treatment as the first cleaning step 15) composed of solvent naphtha (registered trademark) cleaning, acetone cleaning and isopropyl alcohol cleaning was performed. Then, for the purpose of removing the processing-modified layer due to the polishing of the GaN substrate, a chlorine-based plasma dry etching was performed. Further, the GaN substrate was subjected to the second cleaning step in which the GaN substrate was immersed in the buffer hydrofluoric acid solution for 10 minutes, subjected to running purified water cleaning for 10 minutes, dried with nitrogen, then immersed in the sulfuric acid-hydrogen peroxide mixture set at 120° C. for 10 minutes and further subjected to running purified water cleaning, and after the second cleaning step, the GaN substrate was dried with nitrogen.

After the planarization and cleaning, the surface roughness was measured again and the surface roughness Ra=0.5 nm was obtained (“G”). The macro-defect area was decreased by the planarizing step to be 0.16% (“G”). In other words, when an epitaxial film growth was performed on the GaN substrate produced by setting the heat treatment temperature at 1200° C. in Example 2, no macro-defect increase was found. From this fact, it has been found that even when the heat treatment temperature is as high as 1200° C., a GaN substrate exerting no adverse effects on the growth of the epitaxial film can be provided by removing the sodium (Na), the flux component and by planarizing the GaN substrate.

(The Case of the Heat Treatment Temperature of 1300° C.)

By the heat treatment at 1300° C., the surface roughness Ra of the GaN was degraded to 22.3 nm (“P”), and the macro-defect area ratio was also made to be 10.3% (“P”) and the balloon-shaped macro-defects were increased. This is ascribable to the fact that by the heat treatment at 1300° C., the nitrogen in the GaN substrate was eliminated to decompose the GaN crystal surface, and the Ga of the GaN crystal attached in a droplet condition. In this case, it is necessary to remove the balloon-shaped Ga generated at the time of the heat treatment, before the planarizing step. However, even when the planarizing step is performed under this condition, the step comes to be extremely complicated, and hence the productivity is degraded.

From the above-described results, it has been verified that after the group III nitride crystal substrate is produced by slicing the group III nitride crystal grown by the flux liquid phase growth method, by performing the heat treating step in an nitrogen-containing gas atmosphere at a temperature which is equal to or higher than the boiling point of the flux and at which the group III nitride crystal is not decomposed, the flux exerting adverse effects at the time of the growth of the epitaxial film can be removed and thus a satisfactory group III nitride crystal substrate can be provided.

In the description presented above, the case where GaN was used as an example of the group III nitride was described; however, the present invention can also be applied in the same manner to the case where substrates are produced by using other group III nitrides.

The case where the group III nitride crystal is produced by the flux liquid phase growth method using an alkali metal has been described; however, the present invention can also be applied in the same manner to the case where the group III nitride crystal is produced by the ammonothermal method using ammonia as the flux. In the ammonothermal method, the present invention can also be applied particularly to the case where an alkali metal or an alkali earth metal is used as a mineralizer.

In the description presented above, described was the case where the transmission mode of the microscope was used as the method for evaluating the macro-defects. On the other hand, the macro-defect amount may be evaluated by using a precise optical scanner. Alternatively, the macro-defect amount may also be evaluated from the light scattering amount of laser light. In the evaluation of the macro-defects using a precise optical scanner or laser light, it is preferable to examine the defects in the thickness direction of the crystal as extensively as possible. For that purpose, it is more preferable to examine the crystal by using a precise scanner in the transmissive mode, or to examine the crystal in an examination mode in which the laser beam reaches the backside of the crystal in the case where an examination apparatus uses laser scattering. When the reflection mode is used, it is preferable to examine the macro-defects present, inside the crystal, as far as the close proximity of the backside, by using for example the light reflection on the crystal backside or the like.

The sizes of the macro-defects are not particularly limited; the sizes of the macro-defects are varied depending on the request from the semiconductor device that uses the substrate. However, preferable as the optical examination step is an examination step capable of examining the whole surface of the crystal substrate in a relatively short time and capable of examining macro-defects of 0.1 μm or more.

When the macro-defects are quantified, it is preferable to quantify, as the defect area ratio, the above-described ratio of the macro-defective portion area to the whole examined area.

### Example 3

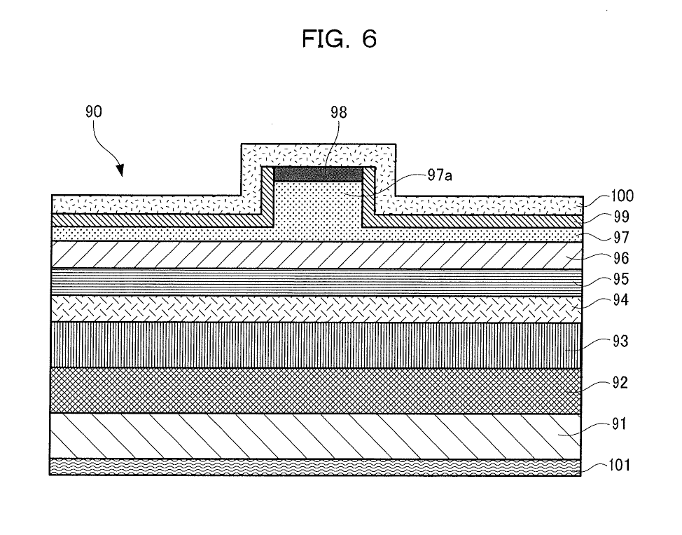

By using the group III nitride crystal substrate obtained in above-described Examples 1 and 2, a semiconductor laser diode was produced as a semiconductor device. Description is made with reference to FIG. 6. FIG. 6 is a sectional view illustrating the structure of a semiconductor laser diode 90 of Example 3 of the present invention.

First, an n-type GaN layer 92 having a film thickness of 2 μm was formed on the surface of an n-type GaN substrate 91, to which germanium (Ge) was added, produced by the methods of Examples 1 and 2. Silicon (Si) was added to the n-type GaN layer 92, by using the MOCVD method (metal organic chemical vapor deposition method) so as for the carrier concentration to be 5×10¹⁸ cm⁻³ or less (for example, 0.7×10¹⁸ cm⁻³).

Next, a clad layer 93 composed of n-type Al_{0.07}Ga_{0.93}N and a light guide layer 94 composed of an n-type GaN were formed on the n-type GaN layer 92. Next, a multiple quantum well (MQW) composed of a well layer (thickness: about 3 nm) composed of Ga_{0.8}In_{0.2}N and a barrier layer (thickness: 6 nm) composed of GaN was formed as an active layer 95. Then, a light guide layer 96 composed of a p-type GaN and a clad layer 97 composed of p-type Al_{0.07}Ga_{0.9}N were formed. On the top of the p-type clad layer 97, a ridge portion 97a to be a current narrowing portion was formed. The semiconductor laser diode 90 is a double heterojunction semiconductor laser, the energy gap of the indium-containing well layer in the MQW active layer 95 is smaller than the energy gap between the aluminum-containing n-type and p-type clad layers 93 and 97. On the other hand, the light refractive index is largest in the well layer of the active layer 95, and decreases in the order of the light guide layer 94, the clad layers 93 and 97.

Then, on the whole surface of the clad layer 97, patterns were formed by using the photolitho technique so as for the lengthwise direction of the light resonator to lie in the <1-100> direction, and thus an insulating film 99 constituting the electric current injection region having a width of about 2 μm was formed. Further, a portion of the insulating film 99, on the top of the ridge portion 97a, was opened and a contact layer 98 composed of a p-type GaN was formed.

Next, on the p-type contact layer 98, a p-side electrode 100 composed of Ni/Au and being in ohmic contact with the contact layer 98 was formed. Further, on the backside of the n-type GaN substrate 91, an n-side electrode 101 composed of Ti/Al and being in ohmic contact with the n-type GaN substrate 91 was formed. Finally, by cleaving in the (1-100) plane, the semiconductor laser diode 90 shown in FIG. 6 was produced. It is to be noted that the stripe width of the laser was 1 μm to 20 μm, and the laser resonator length was 500 μm to 2000 μm.

The device evaluation of the semiconductor laser diode 90 produced by the above-described method was performed. Specifically, when to the obtained semiconductor laser diode 90, a predetermined voltage was applied between the p-side electrode 100 and the n-side electrode 101 in the forward direction, positive holes were injected from the p-side electrode 100 into the MQW active layer 95, and at the same time electrons were injected from the n-side electrode 101 into the MQW active layer. These holes and electrons were recombined in the MQW active layer 95 to yield an optical gain, and thus a laser oscillation occurred at an oscillation wavelength of 404 nm. Further, for the purpose of observing the defect density reduction effect, with a high output mode driven by large current, the reliability of the semiconductor laser diode 90 was evaluated. The semiconductor laser diode 90 was continuously operated at 25° C. at a current density of 5 kA/cm², as the injection current density to give a laser power of 1 W, and thus satisfactory results were obtained. Consequently, it has been found that there can be provided a blue-purple semiconductor laser being free from the effect of the flux component, being driven by large current and having a high power mode.

As described above in respective Examples, when the flux component having a boiling point lower than the epitaxial growth temperature is mixed in the group III nitride crystal produced by the flux growth method, the flux exerting adverse effects on the growth of the epitaxial film can be removed, by heat treating the group III nitride crystal, after the slicing step, in a nitrogen-containing mixed gas atmosphere, at a temperature equal to or higher than the lowest temperature (for example, the boiling point of the flux) capable of discharging the flux from the crystal and lower than the decomposition temperature of the group III nitride crystal, and by subsequently cleaning the group III nitride crystal. Consequently, by the present invention, stable device properties can be realized. By performing the heat treatment based on the present invention before the growth of the epitaxial film, and by examining the surface of the group III nitride crystal substrate, the impurities in the vicinity of the surface of the group III nitride crystal substrate can be removed, and at the same time, the presence and absence of the impurities exerting effects at the time of the growth of the epitaxial film can be inspected.

The group III nitride crystal substrate of the present invention can be applied to various semiconductor devices such as laser diodes, light-emitting diodes and field effect transistors.

### INDUSTRIAL APPLICABILITY

The method for producing a group III nitride crystal substrate of the present invention can remove the flux exerting adverse effects at the time of the growth of the epitaxial film from the group III nitride crystal substrate produced by the flux growth method. Consequently, the production method of the present invention is useful for the method for producing a high-quality group III nitride crystal substrate produced by the flux growth method, the group III nitride crystal substrate, semiconductor devices and others using the group III nitride crystal substrate.

1. A method for producing a group III nitride crystal substrate comprising:
Forming a group III nitride crystal by a growth method using a flux;
Slicing the group III nitride crystal to form a group III nitride crystal substrate; and
Heat treating the group III nitride crystal substrate at a temperature equal to or higher than a lowest temperature at which the flux contained inside the group III nitride crystal substrate through intrusion into the crystal during the crystal formation can be discharged to outside the group III nitride crystal substrate, and equal to or lower than a highest temperature at which a surface of the group III nitride crystal substrate is not decomposed.

2. The method for producing a group III nitride crystal substrate according to claim 1, further comprising removing, by cleaning the group III nitride crystal substrate, the flux discharged by the heat treatment to outside the group III nitride crystal substrate and attached to the substrate.

3. The method for producing a group III nitride crystal substrate according to claim 1, further comprising performing planarization of planarizing the surface of the group III nitride crystal substrate after the heat treatment.

4. The method for producing a group III nitride crystal substrate according to claim 3, wherein the performing planarization comprises at least one of or a combination of two or more of polishing, dry etching and wet etching to planarize the surface of the group III nitride crystal substrate in such a way that a surface arithmetical mean roughness of the group III nitride crystal substrate is 0.1 nm to 5 nm.

5. The method for producing a group III nitride crystal substrate according to claim 1, wherein the group III nitride crystal is sliced, in the slicing, in such a way that a thickness of the group III nitride crystal substrate is 200 μm to 800 μm.

6. The method for producing a group III nitride crystal substrate according to claim 1, wherein in the crystal formation, used is one of a flux comprising at least one of an alkali metal and an alkali earth metal and a flux comprising ammonia in a supercritical state.

7. The method for producing a group III nitride crystal substrate according to claim 6, wherein a flux comprising sodium is used.

8. The method for producing a group III nitride crystal substrate according to claim 7, wherein in the heat treating, a heat treatment is performed at 883° C. or higher and 1200° C. or lower.

9. The method for producing a group III nitride crystal substrate according to claim 6, wherein a flux comprising ammonia in the supercritical state and a mineralizer is used in the crystal formation, and the ammonia and the mineralizer contained inside the group III nitride crystal substrate are discharged to outside the group III nitride crystal substrate in the performing heat treatment.

10. The method for producing a group III nitride crystal substrate according to claim 1, wherein the group III nitride is a compound comprising nitrogen and gallium.

11. The method for producing a group III nitride crystal substrate according to claim 1, further comprising optically examining a macro-defect amount after the heat treatment.

12. The method for producing a group III nitride crystal substrate according to claim 11, wherein an area ratio between defective portions and normal portions of the group III nitride crystal substrate as examined from a principal surface side of the group III nitride crystal substrate is defined as a macro-defect amount.

13. A group III nitride crystal substrate produced by the method for producing a group III nitride crystal substrate according to claim 1, wherein a flux atomic concentration on the surface of the substrate and in a vicinity of the surface of the substrate is lower than a flux atomic concentration in the substrate portion more inner than the surface of the substrate and the vicinity of the surface of the substrate.

14. The group III nitride crystal substrate according to claim 13, wherein the macro-defect amount is capable of being optically examined.

15. The group III nitride crystal substrate according to claim 14, wherein the macro-defect amount is an area ratio between the defective portions and the normal portions of the group III nitride crystal substrate as examined from the principal surface side of the group III nitride crystal substrate.

16. The group III nitride crystal substrate according to claim 14, wherein the macro-defect amount is 1% or less.

17. A semiconductor device produced by forming, on a group III nitride crystal substrate produced by the method for producing a group III nitride crystal substrate according to claim 1, a group III nitride crystal semiconductor layer and a group III nitride crystal semiconductor element disposed on the group III nitride crystal semiconductor layer.

18. The semiconductor device according to claim 17, wherein the group III nitride crystal semiconductor element is one of a laser diode and a light-emitting diode.
